(19) United States
(12) Patent Application Publication
(10) Pub. No.: US 2008/0016415 A1
(43) Pub. Date: Jan. 17, 2008

(54) Evaluation system and method

(75) Inventor: Taketoshi IDE, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 11/819,394

(22) Filed: Jun. 27, 2007

(30) Foreign Application Priority Data
Jun. 29, 2006 (JP) 2006-179625

(51) Int. Cl. G11C 29/00

(52) U.S. Cl. 714/702

(57) ABSTRACT

An evaluation system includes a storage unit, a microcomputer for outputting a read address to the storage unit and executing reading, and an error generator for generating an error signal based on a mode signal and the read address that are transmitted between the storage unit and the microcomputer and outputting the error signal. The microcomputer determines read data received from the storage unit as an error regardless of the read data when the error signal indicates an error in the read data.

### BACKGROUND OF THE INVENTION

1. Field of the Invention

The present invention relates to an evaluation system and its evaluation method and, particularly, to an evaluation system which includes an error generator that reproduces an error which occurs in a storage unit used in a semiconductor device and its evaluation method.

2. Description of Related Art

Some microcomputers include a storage unit for storing a control program, a user program or the like. Recently, a flash memory is widely used as such a storage unit. A flash memory allows the modification of a stored program even after a semiconductor device is manufactured. It is therefore effective in the production of small batches of a variety of semiconductor devices.

A flash memory is also used to store data in addition to storing a user program or the like because stored information is not erased upon power-off. In such a case, it is necessary to write control software such as flash firmware that controls writing and erasing of a flash memory in advance into the flash memory in a microcomputer.

The creation of flash firmware requires debugging to correct a program bug. The debugging process modifies a program by rewriting the program frequently. However, there is a limit to the number of rewrites in a flash memory. The limit to the number of rewrites can hinder the adequate debugging.

There is a technique of performing program debugging using an in-circuit emulator (ICE) having an alternate RAM rather than using a flash memory. An example of the technique of performing program debugging using an ICE is disclosed in Japanese Unexamined Patent Application Publication No. 09-244915.

FIG. 16 is a block diagram showing an evaluation system according to the above related art. The evaluation system includes an evaluation microcomputer 100 and an alternate RAM 108. The evaluation microcomputer 100 includes a central processing unit (CPU) 101, a control register 103 and a support circuit 105. The CPU 101 loads the user program which is stored in the alternate RAM 108 and executes it. By executing the user program, an access control to the alternate RAM 108 is carried out. In the control register 103, data indicating writing or erasing of data in a flash memory is set. Based on the data, the support circuit 105 detects the rule violation in erasing or writing control by the CPU 101. The evaluation system performs debugging of a user program based on the detection result.

Further, there is a program debugging method with the use of an alternate RAM as disclosed in Japanese Unexamined Patent Application Publication No. 11-110244.

However, a flash memory can sometimes fail to write data normally depending on conditions such as an operating voltage and an operating temperature. Thus, the operation of flash firmware involves writing and verification. The writing process writes data into a flash memory, and the verification process compares read data with an expected value of the read data to check if the read data is correct. If the verification process detects an error in a flash memory, error handling such as performing another writing data in the same area or performing another writing after changing a data write region to a different area is carried out.

FIG. 17 shows a flowchart of the operation of flash firmware to explain the related art. As shown in FIG. 17, if the flash firmware is executed, control data indicating writing is set to a control register (S101) Next, a write command 1 is executed (S102). Then, verification of a write result is performed (S103). If there is no error in the verification result, a next write command 2 is executed (S104). On the other hand, if an error is detected in the verification process, error handling is performed (S108). In this manner, commands 1 to 3 are executed, for example, and the verification of the results are performed.

However, a write error which occurs in a flash memory happens under certain conductions and it does not always happen. Therefore, the evaluation system of the above-described related art needs to perform each of Steps S101 to S107 (which are referred to hereinafter as the processing A) for writing and verification and Steps S108 to S110 (hereinafter as the processing B) for error handling and perform verification of each processing.

In the verification of the processing A and the processing B, the processing A and the processing B are executed individually, or they are executed as one program. When executing the processing A and the processing B individually, it is necessary to perform debugging for the processing A and debugging for the processing B separately and further to combine the processing A and the processing B, which complicates the procedure. Further, when combining the program for the processing A and the program for the processing B, it is unable to verify the combining portion of the processing A and the processing B, which causes a human error or the like to degrade the reliability of the program.

Further, when executing the processing A and the processing B as one program, it is necessary to keep executing the program until a write error occurs or to forcibly reproduce the state in which an error occurs by manipulating the data that is read from an alternate RAM from the outside of the evaluation system. If the program is kept executed until a write error occurs, it is unable to know the timing when an error occurs and therefore the operating efficiency decreases significantly. On the other hand, if the state in which an error occurs is reproduced forcibly, the process reads out the read data from an alternative RAM to the outside of the evaluation system, rewrite the read data, and then performs the verification in the evaluation system using the read data which is rewritten. Thus, the verification on the evaluation system cannot be reproduced faithfully and therefore it is unable to perform accurate program debugging, thus degrading the reliability of the program.

### SUMMARY

In one embodiment, there is provided an evaluation system. The evaluation system includes a storage unit, a microcomputer for outputting a read address to the storage unit and executing reading, and an error generator for generating an error signal based on a mode signal and the read address that are transmitted between the storage unit and the microcomputer and outputting the error signal. The microcomputer determines read data received from the storage unit as an error regardless of the read data when the error signal indicates an error in the read data.

In the evaluation system of this embodiment, the error generator generates an error signal based on a read address and a mode signal. The error generator thereby generates a dummy error signal during the execution of a program. The generated error signal is thereby transmitted to the microcomputer at the same timing as the timing when an error actually occurs in the storage unit. The microcomputer can thereby detect a dummy error based on the error signal in the same process as the process of detecting an error which actually occurs in the storage unit.

Further, because the error signal can be generated as appropriate during the execution of a program, the evaluation system of this embodiment eliminates the need for executing a processing A and a processing B as separate programs. It is thus possible to execute an evaluation target program as one program.

In another embodiment, there is provided a program evaluation method to execute an evaluation target program by a microcomputer and verify an operation of the evaluation target program. The method includes receiving read data from a storage unit based on a read clock output form the microcomputer, outputting an error signal generated based on a mode signal and a read address transmitted between the storage unit and the microcomputer, and determining by the microcomputer the read data as an error regardless of the read data received from the storage unit when the error signal indicates an error in the read data.

The program evaluation method according to one embodiment is a method of executing a program on the above-described evaluation system. According to the method, like the above-described evaluation system, the microcomputer can detect a dummy error based on the error signal in the same process as the process of detecting an error which actually occurs in the storage unit.

An evaluation system and its evaluation method according to the present invention enable the faithful reproduction of an error which occurs in a storage unit and the improvement of the reliability of a program.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a block diagram of an evaluation system according to a first embodiment of the present invention;

FIG. 2 is a view showing the relationship between a condition setting register and an error setting register according to the first embodiment;

FIG. 3 is a detailed block diagram of an access controller and an error generator according to the first embodiment;

FIG. 4 is a timing chart of the operation when handling normal read data in an evaluation system according to the first embodiment;

FIG. 5 is a timing chart of the operation when handling erroneous read data in an evaluation system according to the first embodiment;

FIG. 6 is a timing chart of the operation when treating read data as error data by an error signal generated in an error generator in an evaluation system according to the first embodiment;

FIG. 7 is a flowchart of debugging of flash firmware in an evaluation system according to the first embodiment;

FIG. 8 is a flowchart of debugging of a user program in an evaluation system according to the first embodiment;

FIG. 9 is a block diagram of an evaluation system according to a second embodiment of the present invention;

FIG. 10 is a detailed block diagram of an access controller and an error generator according to the second embodiment;

FIG. 11 is a timing chart of the operation when handling erroneous read data in an evaluation system according to the second embodiment;

FIG. 12 is a block diagram of an evaluation system according to a third embodiment of the present invention;

FIG. 13 is a view showing the relationship between an error setting RAM and an alternate RAM according to the third embodiment;

FIG. 14 is a detailed block diagram of an access controller and an error generator according to the third embodiment;

FIG. 15is a timing chart of the operation when handling erroneous read data in an evaluation system according to the third embodiment;

FIG. 16 is a block diagram of an evaluation system according to a prior art; and

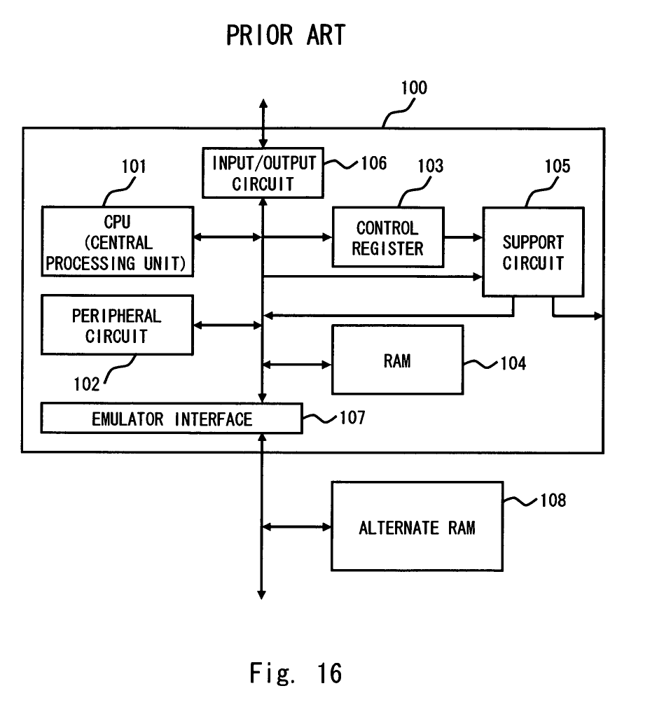

FIG. 17 is a flowchart of debugging of flash firmware in an evaluation system to explain a related art.

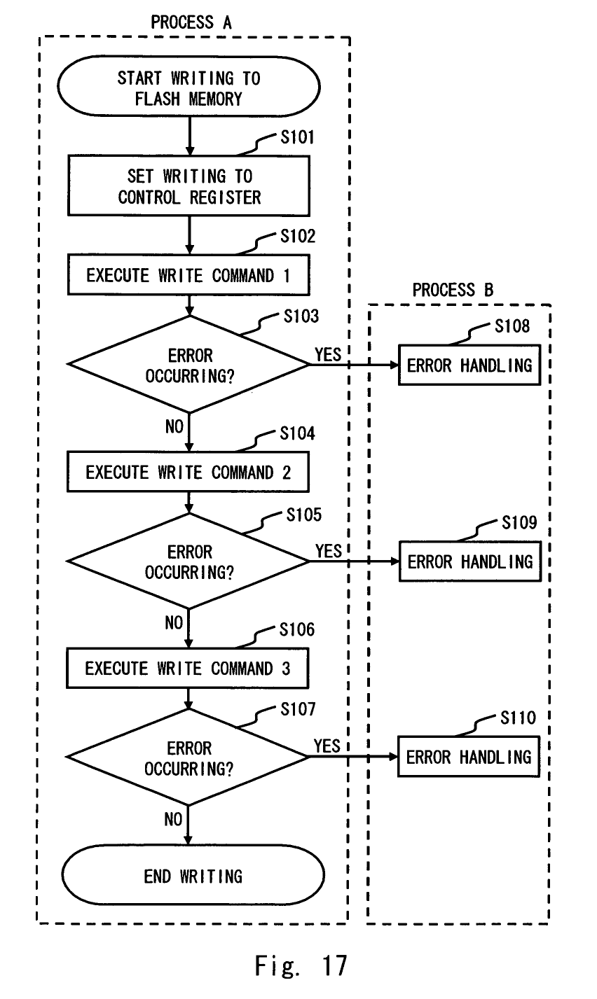

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

Embodiments of the present invention are described hereinafter with reference to the drawings. An evaluation system according to one embodiment of the present invention performs execution and evaluation of a program such as flash firmware. The evaluation of a program is a process of finding and correcting a bug in a program to be evaluated, which is referred to hereinafter also as debugging. The evaluation system 1 is also called an in-circuit emulator, and a plurality of semiconductor devices are placed on an evaluation board. In the present invention, an evaluation microcomputer, an error generator, an alternate RAM, and an external access circuit are placed as semiconductor devices.

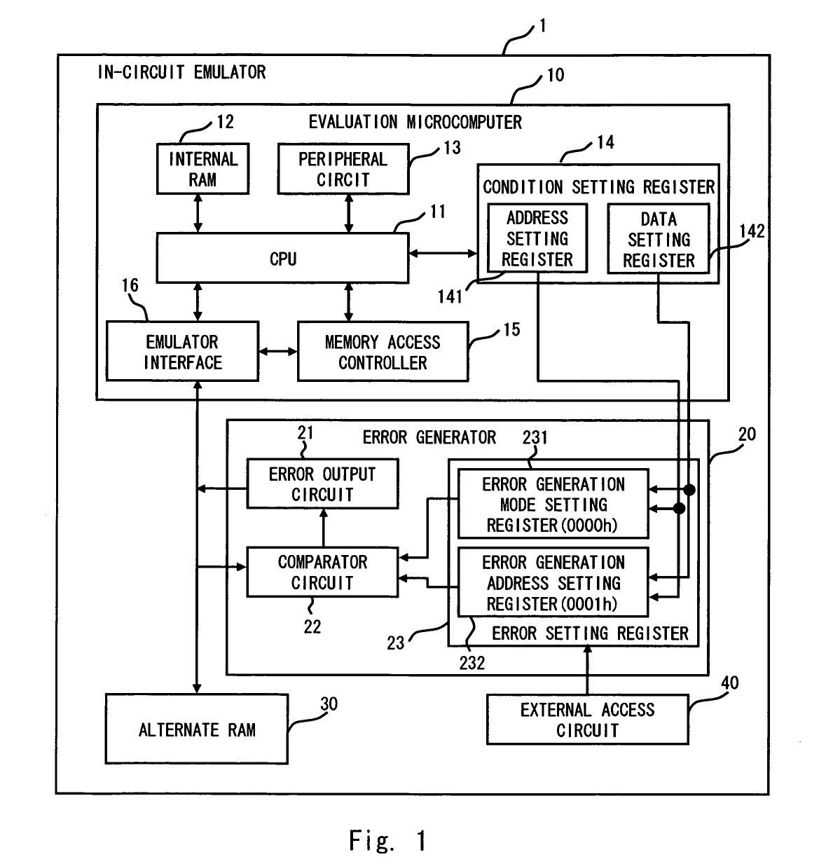

FIG. 1 is a block diagram of the evaluation system 1 according to a first embodiment of the present invention. Referring to FIG. 1, the evaluation system 1 includes an evaluation microcomputer 10, an error generator 20, an alternate RAM 30, and an external access circuit 40. The evaluation microcomputer 10 reads out a program from the alternate RAM 30 and executes it. The error generator 20 artificially generates read data error which occurs in the alternate RAM 30. The alternate RAM 30 is a storage unit which is placed as a substitute for a flash memory that is placed in a shipping product, for example, and it stores a program to be evaluated and data transmitted from the evaluation microcomputer 10. The external access circuit 40 is an interface circuit for connecting the error generator 20 and an external unit (not shown).

The evaluation microcomputer 10 is described hereinafter in detail. The evaluation microcomputer 10 includes a CPU 11, an internal RAM 12, a peripheral circuit 13, a condition setting register 14, a memory access controller 15, and an emulator interface 16. The CPU 11 executes a program and performs various processing. The internal RAM 12 temporarily stores the data which is processed by the CPU 11. The peripheral circuit 13 is a group of circuits which are controlled by the CPU 11, such as an interface circuit between the CPU 11 and a unit that is not shown.

The condition setting register 14 is a data storage area which can be directly controlled by the CPU 11. The condition setting register 14 includes an address setting register 141 and a data setting register 142. The condition setting register 14 sets conditions for generating an error signal in the error generator 20 based on the values stored in those registers. The condition setting register 14 is described in detail later.

The memory access controller 15 controls an access mode of the alternate RAM 30 and performs verification of read data. The verification is a process of comparing read data with an expected value for the read data to check if the read data is correct. The memory access controller 15 is described in detail later. The emulator interface 16 is an interface between the CPU 11 and the error generator 20 and between the CPU 11 and the alternate RAM 30.

The error generator 20 is described hereinafter in detail. The error generator 20 includes an error output circuit 21, a comparator circuit 22, and an error setting register 23. The error output circuit 21 outputs an error signal to the evaluation microcomputer 10. The error signal is a signal to provide notification of an error in read data to the evaluation microcomputer 10. The error signal is generated based on a read address and a mode signal (e.g. verification read mode signal), which are generated in the condition setting register 14 that is set by the evaluation microcomputer 10 regardless of the success or failure of read data.

The comparator circuit 22 compares a value stored in the error setting register 23 with a read address output from the evaluation microcomputer 10. The comparator circuit 22 also compares a value stored in the error setting register 23 with a mode signal. Based on the two comparison results, the comparator circuit 22 outputs a condition match signal to the error output circuit 21. The error setting register 23 includes an error generation mode setting register 231 and an error generation address setting register 232. The error generation mode setting register 231 and the error generation address setting register 232 store a value corresponding to a mode signal and a read address when outputting an error signal, respectively.

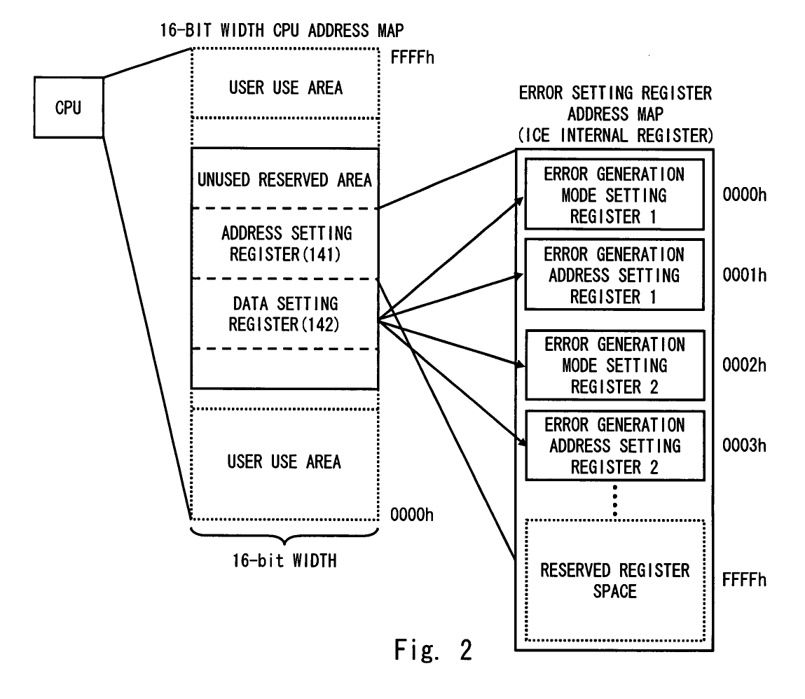

The condition setting register 14 and the error setting register 23 are described hereinafter in detail. FIG. 2 shows the relationship between the condition setting register 14 and the error setting register 23. Referring to FIG. 2, the address setting register 141 and the data setting register 142 of the condition setting register 14 are registers which are defined in an unused, reserved area on an address map of the CPU 11. Thus, the address setting register 141 and the data setting register 142 can be directly controlled by the CPU 11. In the address setting register 141, an address indicating an area on the error setting register 23 to store control data is stored by the CPU 11. Thus, if the address setting register 141 has 16-bit data storage area, it is possible to designate the area on the error setting register 23 at the addresses from “0000h” to “FFFFh”. In the data setting register 142, control data to be stored in the error setting register 23 is stored by the CPU 11.

The error setting register 23 includes a plurality of pairs of an error generation mode setting register and an error generation address setting register. In this embodiment, an error generation mode setting register 1 is set at the address “0000h” on the error setting register 23, and an error generation address setting register 1 is set at the address “0001h” on the error setting register 23. Further, an error generation mode setting register 2 is set at the address “0002h” on the error setting register 23, and an error generation address setting register 2 is set at the address “0003h” on the error setting register 23. FIG. 1 illustrates only one pair of an error generation mode setting register and an error generation address setting register in the error setting register 23 for simplification. However, the number of pairs of an error generation mode setting register and an error generation address setting register may rise to an upper limit of the address of the error setting register 23.

Based on the values which are stored in the address setting register 141 and the data setting register 142, a value is stored into the error setting register 23. As an example, the case of setting values to the error generation mode setting register 1 and the error generation address setting register 1 is described hereinafter. In such a case, the CPU 11 stores the value “0000h” into the address setting register 141. Then, a value corresponding to verification read mode is stored into the data setting register 142. The value corresponding to verification read mode is given as a 4-bit value if there are four modes as the verification read mode, for example. For example, a 4-bit signal sets the value “0001h” for the mode 1, “0002h” for the mode 2, “0004h” for the mode 3, and “0008h” for the mode 4. Each mode is treated as a 1-bit signal and each mode is defined so as to correspond to each of four bit lines, so that other modes are inactive when one mode is active. Because each mode corresponds to each of multi-bit signal lines, the mode comparison in the comparator circuit 22 is easy.

Upon storing a value into the data setting register 142, the error generation mode setting register 1 (address “0000h”) is selected. After that, a mode setting value is stored in the error generation mode setting register 1.

Then, the CPU 11 stores the value “0001h” into the address setting register 141. After that, an address (read address) on the alternate RAM 30 to store the read data in which an error is to be generated is stored into the data setting register 142. Upon storing the value into the data setting register 142, the error generation address setting register 1 (address “0001h”) is selected, and the address (read address) on the alternate RAM 30 to store the read data in which an error is to be generated is stored into the error generation address setting register 1. Values are stored in other error generation mode setting registers and error generation address setting registers in the same procedures as above.

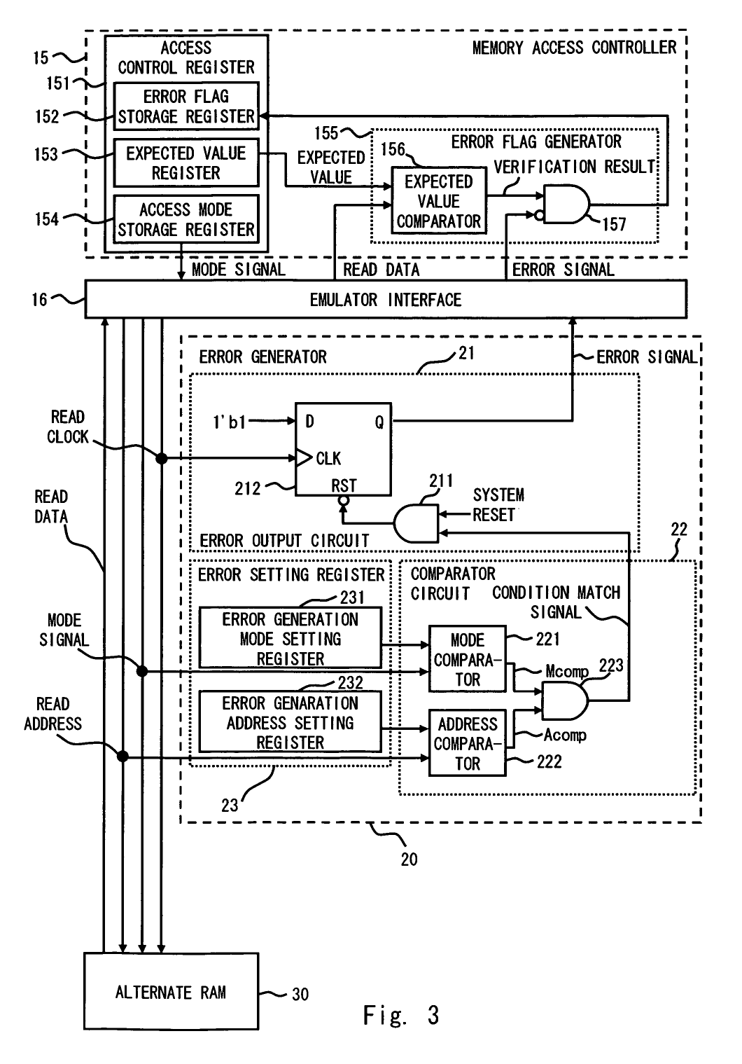

The memory access controller 15 and the error generator 20 are described hereinafter in detail to explain the operation of the evaluation system 1. FIG. 3 is a detailed block diagram of the memory access controller 15 and the error generator 20. Referring to FIG. 3, the memory access controller 15 includes an access control register 151 and an error flag generator 155.

The access control register 151 includes an error flag storage register 152, an expected value register 153, and an access mode storage register 154. In the error flag storage register 152, “1” is stored if read data matches with an expected value, and “0” is stored if they do not match. The value of the error flag storage register 152 is input from the error flag generator 155. The value which is stored in the error flag storage register 152 is read out by the CPU 11 and is used as a result of verification. The expected value register 153 holds an expected value for the read data which is input from the CPU 11. The expected value is transmitted to the error flag generator 155. The access mode storage register 154 holds a value corresponding to a mode signal which is transmitted from the CPU 11. The value corresponding to a mode signal is a value which is given to each operation such as writing, erasing or reading in the alternate RAM 30, and it is supplied as a mode signal to the alternate RAM 30 through the emulator interface 16. The alternate RAM 30 carries out various operations based on the value of the mode signal.

The error flag generator 155 includes an expected value comparator 156 and an AND circuit 157. The expected value comparator 156 compares the expected data which is stored in the expected value register 153 with the read data which is read from the alternate RAM 30 and input through the emulator interface 16 and outputs a verification result. The verification result is High level when the expected value and the read data match and it is Low level when they do not match.

The AND circuit 157 receives the verification result and the error signal which is input from the error generator 20 through the emulator interface 16. The AND circuit 157 outputs the logical AND of the verification result and an inverted logic of the error signal. The output of the AND circuit 157 serves as the output of the error flag generator 155. Specifically, the error flag generator 155 stores “0” into the error flag storage register 152 when the error signal is a first state (e.g. a logic value which is High level and indicates occurrence of an error) and it stores a value based on the output of the expected value comparator 156 into the error flag storage register 152 when the error signal is a second state (e.g. a logic value which is Low level and indicates no occurrence of an error).

The error generator 20 includes the error output circuit 21, the comparator circuit 22 and the error setting register 23. The error setting register 23 includes the error generation mode setting register 231 and the error generation address setting register 232. The error generation mode setting register 231 outputs an error generation mode signal corresponding to the access mode that generates an error signal based on a stored value. The error generation address setting register 232 outputs an error generation address indicating an address on the alternate RAM 30 to store the read data in which an error is to be generated based on a stored value.

The comparator circuit 22 includes a mode comparator 221, an address comparator 222, and an AND circuit 223. The mode comparator 221 compares an error generation mode value which is stored in the error generation mode setting register 231 with a value of a mode signal which is transmitted from the emulator interface 16 to the alternate RAM 30 and outputs a mode comparison result Mcomp. The mode comparison result Mcomp is High level when the error generation mode value and the mode signal value match, and it is Low level when they do not match. The address comparator 222 compares an error generation address which is stored in the error generation address setting register 232 with a read address which is transmitted from the emulator interface 16 to the alternate RAM 30 and outputs an address comparison result Acomp. The address comparison result Acomp is High level when the error generation address and the read address match, and it is Low level when they do not match. The AND circuit 223 outputs the logical AND of the mode comparison result Mcomp and the address comparison result Acomp. The output of the AND circuit 223 serves as the output of the comparator circuit 22, and it is referred to as a condition match signal. The error generation mode setting register 231 and the error generation address setting register 232 are registers of the error setting register 23 as described earlier.

FIG. 3 illustrates only one pair of an error generation mode setting register and an error generation address setting register for simplification. When using a plurality of pairs of error generation mode setting registers and error generation address setting registers, the comparator circuit 22 is placed for each of the plurality of register pairs, and a logical OR of outputs of the plurality of comparators 22 is input to the error output circuit 21.

The error output circuit 21 includes an AND circuit 211 and a latch circuit 212. The AND circuit 211 receives a system reset signal at one input and a condition match signal at the other input. The AND circuit 211 outputs a logical AND of the two inputs. The latch circuit 212 is a D-latch circuit, for example, and its data input terminal D is fixed to High level (1′b1). A reset input terminal RST of the latch circuit 212 is connected to the AND circuit 211, and the latch circuit 212 is in the reset state when the output of the AND circuit 211 is Low level. In the reset state, the latch circuit 212 outputs Low level from its output terminal Q. In the reset clear state (when the output of the AND circuit 211 is High level), the latch circuit 212 outputs High level that is input to the data input terminal D in response to the rising edge of a read clock. The output of the latch circuit 212 serves as an error signal. Specifically, the error output circuit 21 sets the error state (e.g. read data error state) of an error signal in synchronization with the read clock and clears the error state of the error signal based on the output of the comparator circuit 22. The system reset signal is a signal which is input from the outside of the error generator 20 and used to set whether or not to activate the error generator 20.

The operation of the evaluation system 1 according to this embodiment is described hereinafter. As an example of the operation, the verification of read data is described. The verification processing involves the operation where there is no error in read data and the operation where there is an error in read data.

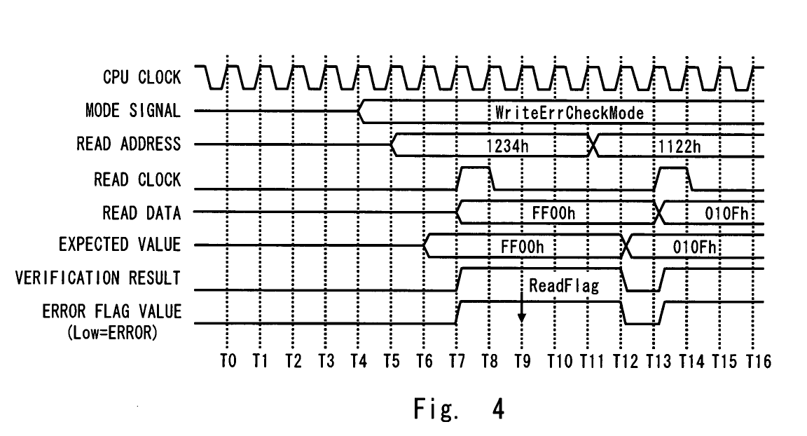

The operation where no error occurs in read data is described hereinafter. In this condition, a system reset signal is Low level, and the error generator 20 sets an error signal to Low level. FIG. 4 is a timing chart of the operation in the condition where there is no error in read data. First, at the timing T4, the mode signal “WriteErrCheckMode”, which indicates the verification mode, is output from the evaluation microcomputer 10. Next, at the timing T5, a read address indicating the address “1234h” is output from the evaluation microcomputer 10. At the timing T6, the expected data “FF00h” of read data is set to the expected value register 153. Then, at the timing T7, a read clock is output from the evaluation microcomputer 10, and the read data “FF00h” is output from the alternate RAM 30 in response thereto. The read data which is output from the alternate RAM 30 is compared with the expected value by the expected value comparator 156. Because the read data value and the expected value match, the verification result is High level. Since the error signal is Low level, the output of the AND circuit 157 is the same logic level as the verification result. Therefore, “1” is stored into the error flag storage register 152. The evaluation microcomputer 10 reads the error flag value at the rising edge of the CPU clock at the timing T9, thereby detecting that the read data is correct.

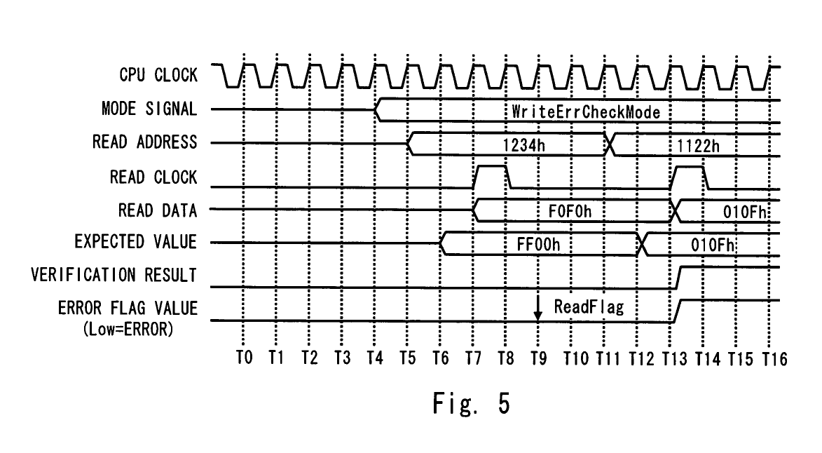

The operation where an error occurs in read data is described hereinafter. In this condition, a system reset signal is Low level, and the error generator 20 sets an error signal to Low level. FIG. 5 is a timing chart of the operation in the condition where there is an error in read data. First, at the timing T4, the mode signal “WriteErrCheckMode”, which indicates the verification mode, is output from the evaluation microcomputer 10. Next, at the timing T5, a read address indicating the address “1234h” is output from the evaluation microcomputer 10. At the timing T6, the expected data “FF00h” of read data is set to the expected value register 153. Then, at the timing T7, a read clock is output from the evaluation microcomputer 10, and the read data “F0F0h” is output from the alternate RAM 30 in response thereto. The read data which is output from the alternate RAM 30 is compared with the expected value by the expected value comparator 156. Because the read data value and the expected value do not match, the verification result is Low level. Since the error signal is Low level, the output of the AND circuit 157 is the same logic level as the verification result. Therefore, “0” is stored into the error flag storage register 152. The evaluation microcomputer 10 reads the error flag value at the rising edge of the CPU clock at the timing T9, thereby detecting that the read data is incorrect.

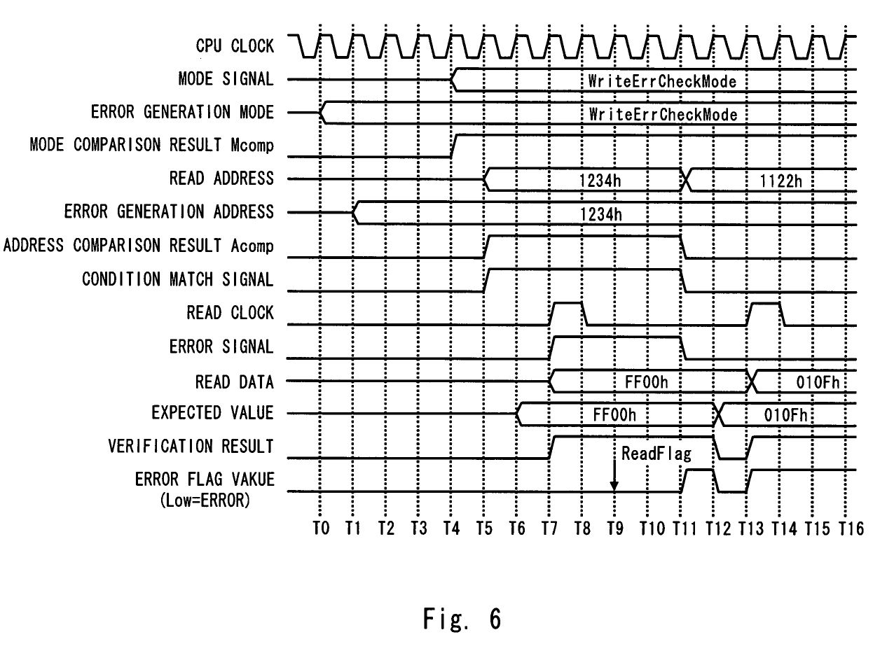

The operation where read data becomes an error in accordance with an error signal is described hereinafter. FIG. 6 is a timing chart where read data becomes an error based on an error signal. First, at the timing TO, the mode signal value that causes an error to be generated is set to the error generation mode setting register 231. In this example, “WriteErrCheckMode” is set as the value of the mode signal. Next, at the timing T1, the address of the alternate RAM 30 to store the read data in which an error is to be generated is set to the error generation address setting register 232. In this example, “1234h” is set as such an address.

Then, at the timing T4, the mode signal “WriteErrCheckMode”, which indicates the verification mode, is output from the evaluation microcomputer 10. The error generation mode value and the mode signal value thereby match, and the mode comparison result Mcomp becomes High level. Next, at the timing T5, a read address indicating the address “1234h” is output from the evaluation microcomputer 10. The error generation address value and the read address value thereby match, and the address comparison result Acomp becomes High level. Because the mode comparison result Mcomp and the address comparison result Acomp are both High level, a condition match signal becomes High level. The condition match signal remains High level until either one of the mode comparison result Mcomp or the address comparison result Acomp becomes Low level.

After that, at the timing T6, the expected data “FF00h” of read data is set to the expected value register 153. Then, at the timing T7, a read clock is output from the evaluation microcomputer 10, and read data “FF00h” is output from the alternate RAM 30 in response thereto. The read data which is output from the alternate RAM 30 is compared with the expected value by the expected value comparator 156. Because the read data value and the expected value match, the verification result is High level. However, since the condition match signal is High level, the error signal which is output from the error output circuit 21 becomes High level according to the read clock. Therefore, the output of the AND circuit 157 is Low level regardless of the verification result. Accordingly, “0” is stored into the error flag storage register 152. The evaluation microcomputer 10 reads the error flag value at the rising edge of the CPU clock at the timing T9, thereby detecting that the read data is incorrect.

The error flag value temporarily becomes High level from the timing T11 to T12. This is because the read address changes at the timing T11 and the error signal changes from High level to Low level, so that the mask of the verification result is temporarily disabled. However, the change does not affect the result of the verification because the error flag value is captured into the evaluation microcomputer 10 at the timing T9.

As described above, in the evaluation system 1 of this embodiment, the error generator 20 generates an error signal based on a mode signal and a read address and outputs it in response to a read clock. Further, the evaluation system 1 masks a verification result which is generated based on an expected value of read data and the read data by the error signal and stores an error flag indicating the occurrence of an read error into the error flag storage register 152. The evaluation microcomputer 10 can thereby read the result of the verification by the CPU 11 in the same process regardless of the presence or absence of read error. Further, the CPU11 can detect the occurrence of an error without fail. On the other hand, in an evaluation system of a related art, it is necessary to read the read data from an alternate RAM to the outside of the evaluation system, rewrite the read data, and perform verification using the rewritten read data to determine if there is an error. The evaluation system 1 of this embodiment only needs to mask the verification result of read data and does not need the process of rewriting the read data. The evaluation system 1 can thereby faithfully reproduce a read error which would actually occur.

Further, although it is difficult for an evaluation system of a related art to reproduce an error which occurs accidentally in a flash memory or the like, the evaluation system 1 of this embodiment can faithfully reproduce the detection of an error using an error signal which is generated forcibly. In addition, it is possible to generate an error signal not only for an alternate RAM but also for a nonvolatile memory by changing the connection of the error generator in the evaluation system 1 and appropriately setting the value of the error setting register. It is therefore possible to generate an error which occurs only accidentally in a nonvolatile memory by the error generator. This enables efficient debugging of a program related to error handling, which should be performed in the control of a nonvolatile memory.

Further, the evaluation system 1 of this embodiment can reproduce an error in a given state and at a given read address by changing the values of the error generation mode setting register 231 and the error generation address setting register 232. Furthermore, the evaluation system 1 of this embodiment can reproduce an error which occurs under a plurality of conditions by placing a plurality of sets of the error generation mode setting register 231, the error generation address setting register 232 and the comparator circuit 22. It is thereby possible to set the state where an error occurs in all read addresses, for example. By executing a program to be evaluated under such conditions, it is possible to easily detect a bug that an error which occurs in a particular address is undetectable. Evaluating a program using the evaluation system 1 of this embodiment increases the reliability of the program.

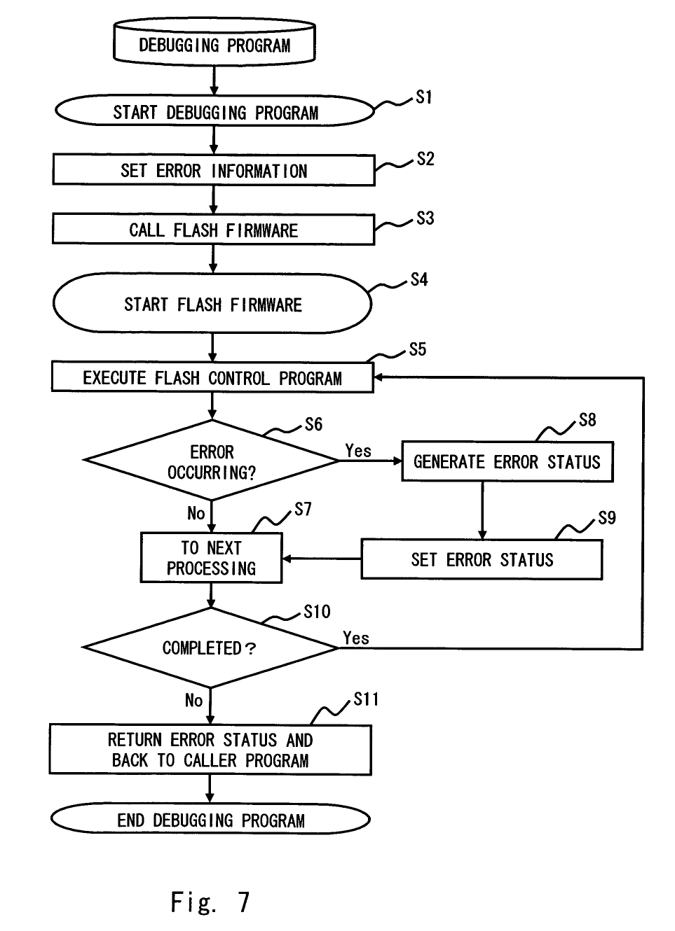

The debugging of flash firmware using the evaluation system 1 of this embodiment is described hereinafter. The flash firmware is called when a user program performs an operation such as data writing to a storage unit, for example, and controls the storage unit according to an instruction from the user program. The flash firmware performs verification as one of its functions. The debugging of flash firmware when a debugging program which is prepared for debugging of flash firmware is used in place of a user program is described hereinafter. Thus, a program to be evaluated is flash firmware in the following example. FIG. 7 is a flowchart showing the process of debugging flash firmware.

Referring to FIG. 7, in the process of debugging flash firmware, the CPU 11 firstly calls a debugging program from the alternate RAM 30 and executes the debugging program (S1). Because an error information setting step is described at the top of the debugging program, error information is set after Step S1 (S2). In Step S2, the CPU 11 sets a value to be stored into the error setting register 23 through the condition setting register 14 based on the information defined by the debugging program. After that, the debugging program calls flash firmware from the alternate RAM 30 and stores it into the internal RAM 12, for example (S3). The CPU 11 then executes the flash firmware which is stored in the internal RAM 12 (S4).

Then, the CPU 11 controls the alternate RAM 30 using the flash firmware (S5). At this time, it is determined whether an error occurs in the operation in response to the control (S6). The evaluation system 1 of this embodiment can generate an error state using the error generator in Step S6. If it is determined in Step S6 that there is no error occurring, the CPU 11 proceeds to the next processing, such as making an access to the next address on the alternate RAM 30 (S7).

On the other hand, if a read error occurs or an error signal is generated by the error generator 20, an error flag which indicates an error in read data is stored into the error flag storage register 152, and the CPU 11 generates an error status indicating the occurrence of an error (S8). The error status may be “1Ah” when an error occurs in the mode 1 and “1Bh” when an error occurs in the mode 2, for example. If the flash firmware has an error handling function such as performing another writing at the address where an error occurs in the event of an error, the process may include such an error handling step. After Step S8, the error status is held in the internal RAM 12 (S9). After that, the CPU 11 proceeds to Step S7.

The CPU 11 determines whether the operation of the flash firmware is completed (S10). If it is determined in Step S10 that the execution of the flash firmware is not completed, the process returns to Step S5. On the other hand, if it is determined that the execution of the flash firmware is completed, the CPU 11 returns the error status which is held in the internal RAM 12 as a returned value and switches the mode to execute the debugging program (S11).

As described above, the process generates an error signal by the error generator 20, executes an error handling code of flash firm ware, and determines whether an error status which is generated after the execution matches with an expected value, thereby performing debugging of the flash firmware. Further, the use of the evaluation system 1 enables to execute the error handling processing and the writing and verification processing as one program rather than executing them individually. This prevents a bug which is caused by combining separated programs and thereby increases the reliability of the program.

The evaluation system 1 of this embodiment is also effective in debugging a user program which is created by a user. In such a case, a program to be evaluated is a user program. An example of the process of debugging a user program is described hereinbelow. In the following example, a user program has a function of calling flash firmware and it is stored in the alternate RAM 30. The CPU 11 executes the user program which is stored in the alternate RAM 30. If a user program is debugged in an ICE, a supervisor program is used as a debugging program. The supervisor program may be stored in the alternate RAM 30 or in a storage unit different from the alternate RAM 30. The ICE has a break function that suspends a program which is being executed by the CPU 11. With the break function, the supervisor program can manipulate the data that is stored in the register which is accessible by the CPU 11 or in a storage area while the operation of the user program is suspended.

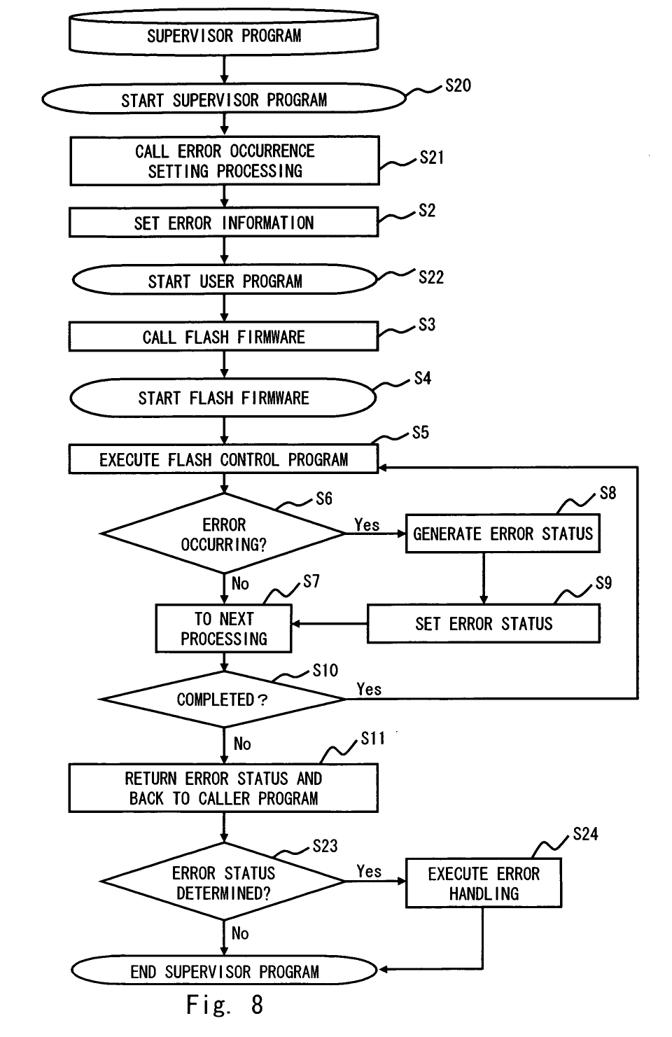

FIG. 8 is a flowchart showing the process of debugging a user program. In such a case, a supervisor program is launched upon executing the bleak function of the ICE (S20). Then, the processing of setting error occurrence is called by the supervisor program (S21). In response to the operation of Step S21, the CPU 11 sets a value to be stored into the error setting register 23 through the condition setting register 14 (S2).

After that, the CPU 11 clears the break state of the ICE and executes the user program (S22). The user program calls flash firmware from the alternate RAM 30 (S3). The flash firmware which is called in Step S3 is stored into the internal RAM 12, and the CPU 11 controls the alternate RAM 30 using the flash firmware (S4). The operation of Steps S5 to S10 using the flash firmware are practically the same as the operation of the flash firmware shown in FIG. 7.

Then, the error status which is generated by the flash firmware is transmitted as an execution result of the flash firmware to the user program. The CPU 11 switches the mode to execute the user program (S11). The CPU 11 then executes the user program and makes a judgment on the error status which is received in Step S11 (S23). As a result of the judgment in Step S23, if the error status does not require further processing, the process ends the user program. If, on the other hand, the error status requires error handling in the subsequent step, the process carries out the error handling and then ends the user program (S24). The error handling which is performed in Step S24 may be performing another writing into an area different from the area where the error occurs or displaying an error status on an external display device, for example.

As described above, the use of the evaluation system 1 of this embodiment enables program debugging without changing read data or error status during execution of a program. The evaluation system 1 of this embodiment can set an arbitrary error occurrence condition using an ICE break function or a supervisor program and generate an error signal based on the condition. It can further execute an error handling code of flash firmware according to the error signal and debug a user program using an error status which is generated after the execution. The evaluation system 1 can thereby perform program debugging more smoothly than an evaluation system of a related art. In an evaluation system of a related art, it is necessary when generating an error to read the read data to the outside of the evaluation system, rewrite the read data, and perform verification in the evaluation system using the rewritten read data, which hinders efficient debugging.

### Second Embodiment

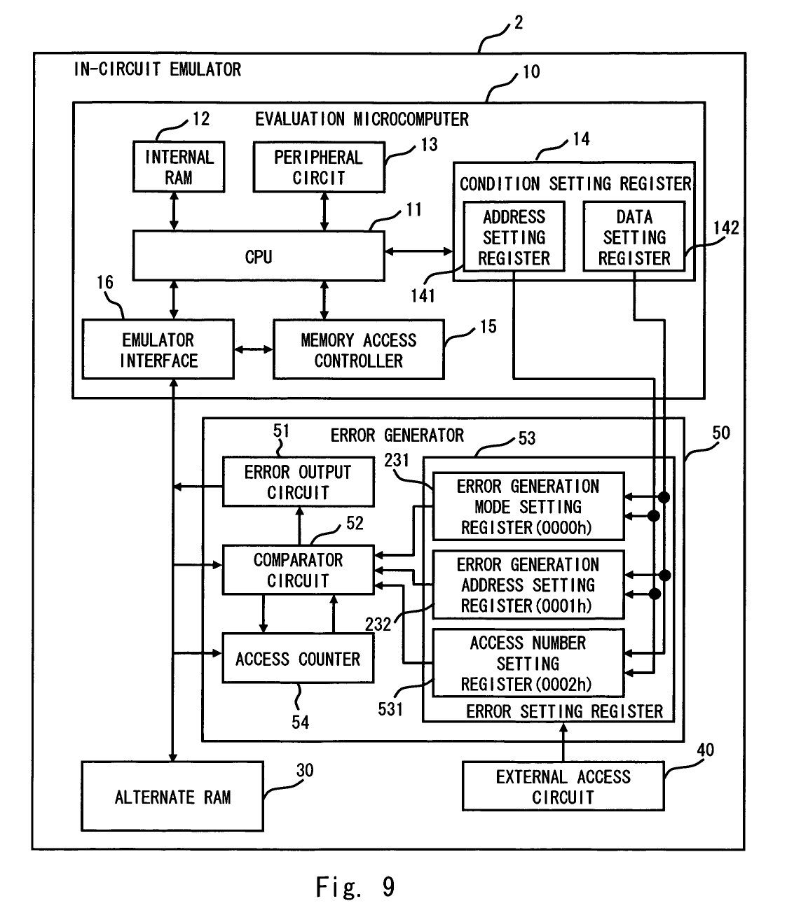

FIG. 9 is a block diagram of an evaluation system 2 according to a second embodiment of the present invention. In FIG. 9, the same elements as in the first embodiment are denoted by the same reference symbols and not described in detail herein.

The evaluation system 2 of the second embodiment is different from the evaluation system 1 of the first embodiment in the configuration of the error generator. The error generator 20 of the first embodiment generates an error signal based on a mode signal and a read address. On the other hand, an error generator 50 of the second embodiment generates an error signal based on a mode signal, a read address and the number of accesses to the read address.

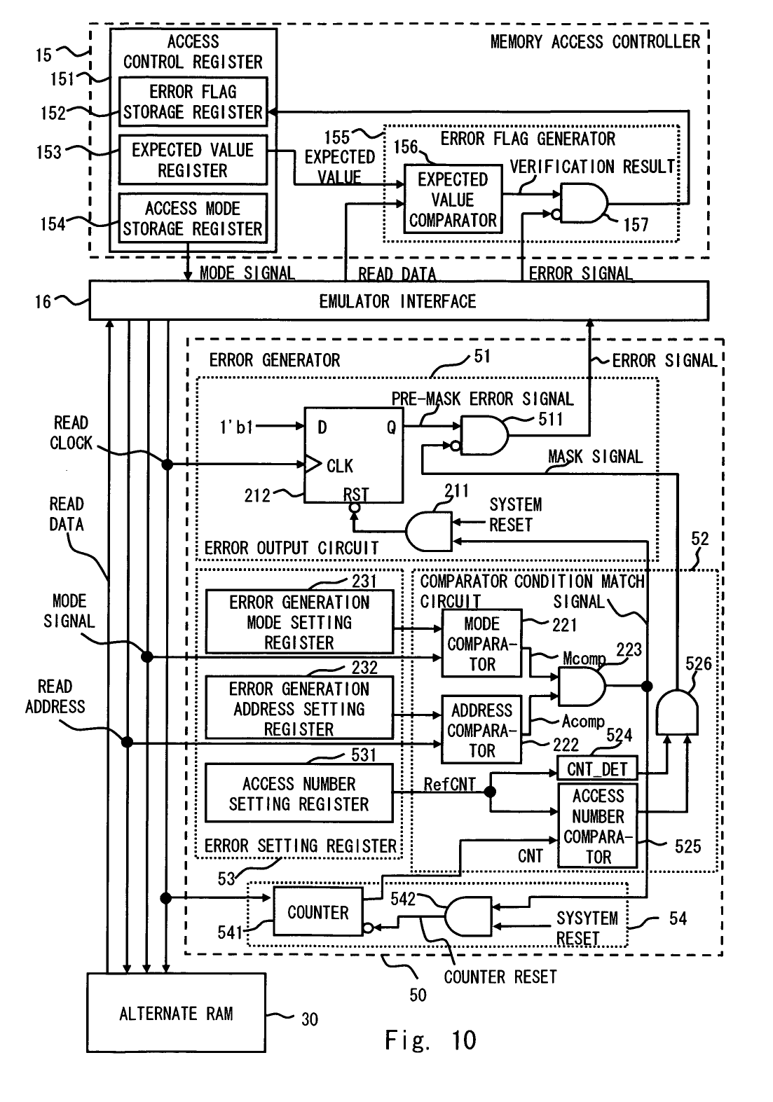

Referring to FIG. 9, the error generator 50 includes an access counter 54 and an access number setting register 531 in addition to the configuration of the error generator 20. The access number setting register 531 is defined within the area of an error setting register 53. FIG. 10 is a detailed block diagram of the error generator 50.

The error generator 50 according to the second embodiment outputs an error signal until the access to the condition which is set by the error generation mode setting register 231 and the error generation address setting register 232 reaches a predetermined number. If the number of access to the condition reaches a predetermined number, it stops an error signal (i.e. clears the error state). Referring to FIG. 10, the error generator 50 includes an error output circuit 51, a comparator circuit 52, the error setting register 53, and the access counter 54.

The access counter 54 includes a counter 541 and an AND circuit 542. The counter 541 is in the reset clear state when a counter reset signal is High level, so that it counts the number of read clocks after the reset is cleared and outputs it as a count value CNT. On the other hand, the counter 541 is in the reset state when a counter reset signal is Low level, so that it stops counting the number of read clocks and resets the count value CNT to “0”. The counter reset signal is generated in the AND circuit 542. The AND circuit 542 outputs Low level when the system reset signal is Low level, and it outputs the same logic level as the condition match signal when the system reset signal is High level. Thus, the counter reset signal has the same logic level as the condition match signal when the system reset signal is High level.

The error setting register 53 includes the access number setting register 531 in addition to the configuration of the error setting register 23 according to the first embodiment. The value which is stored into the access number setting register 531 is set based on the value of the condition setting register 14 of the evaluation microcomputer 10 in the same procedure as the error generation mode setting register 231 and the error generation address setting register 232. The access number setting register 531 outputs a reference count value RefCNT based on the stored value.

The comparator circuit 52 includes a reference count value detector 524, an access number comparator 525, and an AND circuit 526 in addition to the configuration of the comparator circuit 22 of the first embodiment. The reference count value detector 524 outputs Low level when the reference count value RefCNT indicates “0” and outputs High level when the reference count value RefCNT indicates a value different from “0”. The access number comparator 525 compares the count value CNT with the reference count value RefCNT. The access number comparator 525 outputs Low level when the count value CNT and the reference count value RefCNT do not match, and it outsputs High level when the count value CNT and the reference count value RefCNT match. The AND circuit 526 outputs a logical AND between the output of the reference count value detector 524 and the output of the access number comparator 525. Thus, if the output of the reference count value detector 524 is High level, the output of the AND circuit 526 is the same logic level as the output of the access number comparator 525. The output of the AND circuit 526 is supplied as a mask signal to the error output circuit 51.

The error output circuit 51 includes an AND circuit 511 in addition to the configuration of the error output circuit 21 of the first embodiment. In the second embodiment, the output of the latch circuit 212 is referred to as a pre-mask error signal. The AND circuit 511 outputs a logical AND between the inverted signal of the mask signal and the pre-mask error signal. If the mask signal is Low level, the output of the AND circuit 511 is the same logic level as the pre-mask error signal. If, on the other hand, the mask signal is High level, the AND circuit 511 outputs Low level regardless of the logic level of the pre-mask error signal. The output of the AND circuit 511 serves as an error signal.

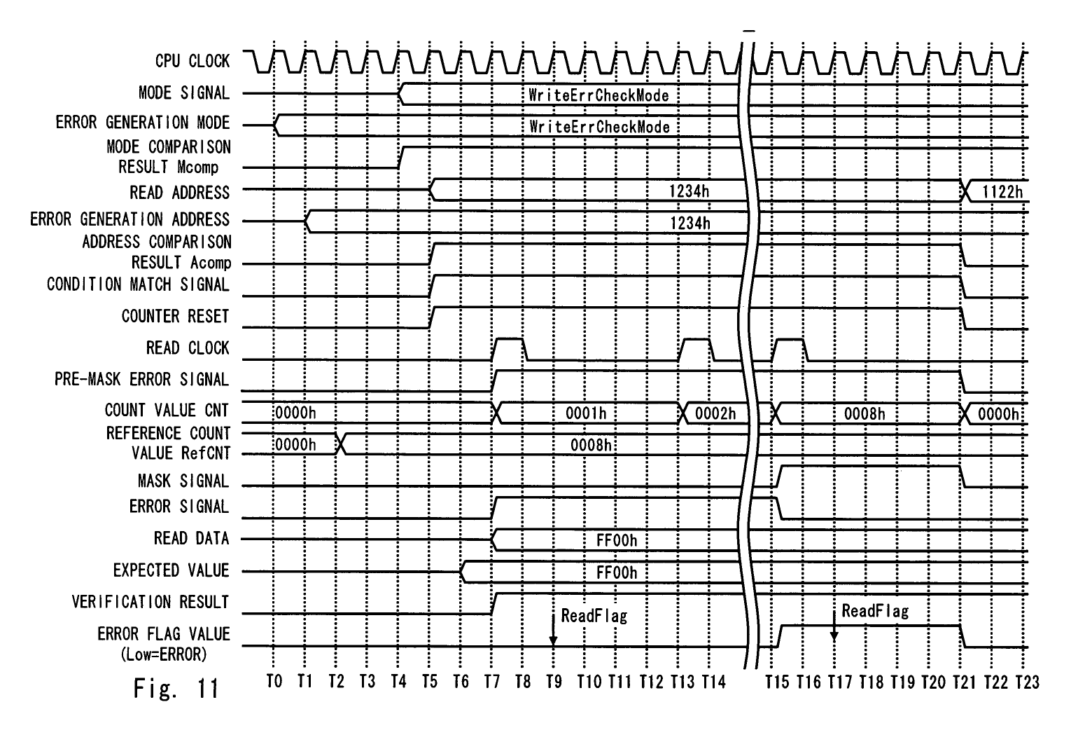

The operation of the error generator 50 according to the second embodiment is described hereinafter. FIG. 11 is a timing chart of the operation of the evaluation system 2 when the error generator 50 is in operation. First, at the timing T0, the mode signal value that causes an error to be generated is set to the error generation mode setting register 231. In this example, “WriteErrCheckMode∞ is set as the value of the mode signal. Next, at the timing T1, the address of the alternate RAM 30 to store the read data in which an error is to be generated is set to the error generation address setting register 232. In this example, “1234h” is set as such an address (read address). Further, at the timing T2, a predetermined count number is set to the count number setting register. In this embodiment, “0008h”, which indicates eight times, is set as the predetermined number.

Then, at the timing T4, the mode signal “WriteErrCheckMode”, which indicates the verification mode, is output from the evaluation microcomputer 10. The error generation mode value and the mode signal value thereby match, and the mode comparison result Mcomp becomes High level. Next, at the timing T5, a read address indicating the address “1234h” is output from the evaluation microcomputer 10. The error generation address value and the read address value thereby match, and the address comparison result Acomp becomes High level. Because the mode comparison result Mcomp and the address comparison result Acomp are both High level, the condition match signal becomes High level. The condition match signal remains High level until either one of the mode comparison result Mcomp or the address comparison result Acomp becomes Low level. Further, in the second embodiment, the values of the mode signal and the read address are held until the access number reaches a predetermined number. The counter reset signal becomes High level when the condition match signal becomes High level. The counter 541 thereby enters the state of counting the read clocks.

After that, at the timing T6, the expected data “FF00h” of read data is set to the expected value register 153. Then, at the timing T7, a read clock is output from the evaluation microcomputer 10, and read data “FF00h” is output from the alternate RAM 30 in response thereto. The read data which is output from the alternate RAM 30 is compared with the expected value by the expected value comparator 156. Because the read data value and the expected value match, the verification result becomes High level. Further, because the condition match signal is High level, the pre-mask error signal which is output from the latch circuit 212 becomes High level in accordance with the read clock. On the other hand, the counter 541 counts the read clocks and outputs the count value CNT which has the value “0001h” . However, because the count value does not match with the reference count value RefCNT, the mask signal which is output from the access number comparator 525 is Low level. Accordingly, the output of the AND circuit 511 is High level, which is the same as the pre-mask error signal. The output of the AND circuit 157 is thereby Low level regardless of the verification result. As a result, “0” is stored into the error flag storage register 152. The evaluation microcomputer 10 reads the error flag value at the rising edge of the CPU clock at the timing T9, thereby detecting that the read data is incorrect.

After the timing T13, the access to the condition is repeated, so that the count value CNT is counted up to “0007h”. Because the error signal is Low level during this period, “0” is set to the error flag storage register 152. Then, at the timing T15, the eighth read clock is input, and the count value CNT becomes “0008h”. The output of the access number comparator 525 thereby becomes High level, and the mask signal becomes High level accordingly. The error signal which is output from the AND circuit 511 thereby becomes Low level. The output of the AND circuit 157 becomes High level, which is the same as the verification result, and the error flag value becomes “1”. The error flag value is read at the rising edge of the CPU clock at the timing T17, so that the CPU 11 detects that the read data is correct.

As described above, the evaluation system 2 of the second embodiment can attempt an access to the read address where an error occurs a plurality of times and succeed in writing after repeating the access a predetermined number of times. The evaluation system of the second embodiment can thereby reproduce more complicated error handling than that of the first embodiment. It is therefore possible to implement the evaluation system which can reproduce various access modes or error modes. When generating an error signal for one-time access in the evaluation system 2 of the second embodiment, “0” may be set to the access number setting register 531. The output of the reference count value detector becomes Low level, so that the mask signal which is output from the AND circuit 526 is always Low level. The output of the AND circuit 511 in the error generator 50 is thereby the same logic as the pre-mask error signal. Accordingly, the mask of the pre-mask error signal is always cleared, which enables the same operation as in the first embodiment.

### Third Embodiment

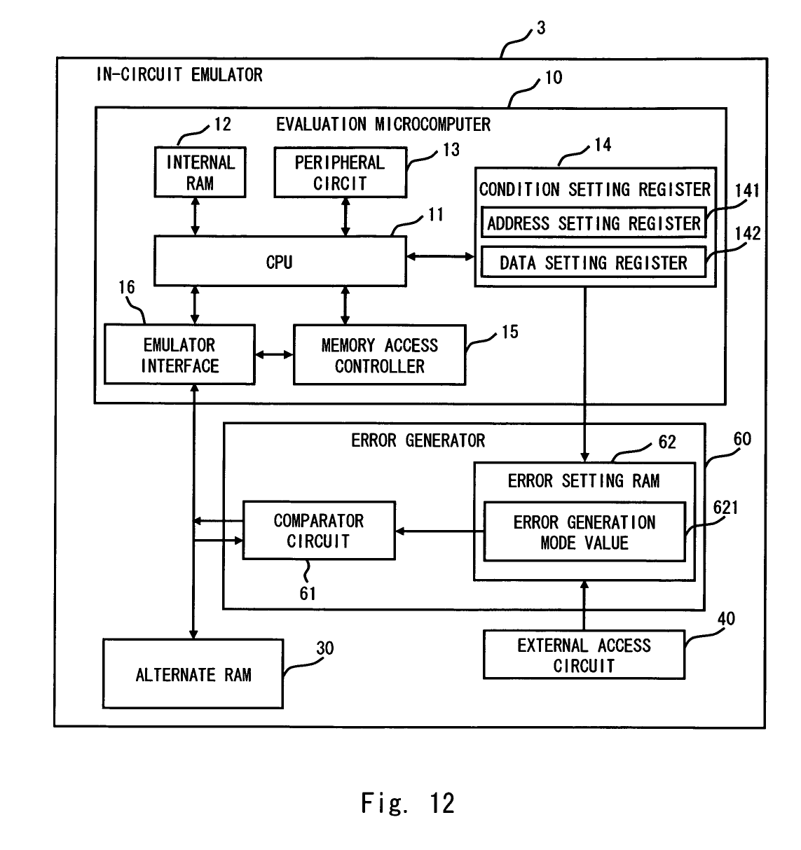

FIG. 12 is a block diagram of an evaluation system 3 according to a third embodiment of the present invention. In FIG. 12, the same elements as in the first embodiment are denoted by the same reference numerals and not described in detail herein.

The evaluation system 3 of the third embodiment is different from the evaluation system 1 of the first embodiment in the configuration of the error generator. The error generator 20 of the first embodiment includes a register that stores an error generation mode and an error generation address to generate an error. On the other hand, an error generator 60 according to the third embodiment includes an error setting RAM 62 that has the same number of error generation mode storage areas as the number of addresses of the alternate RAM 30.

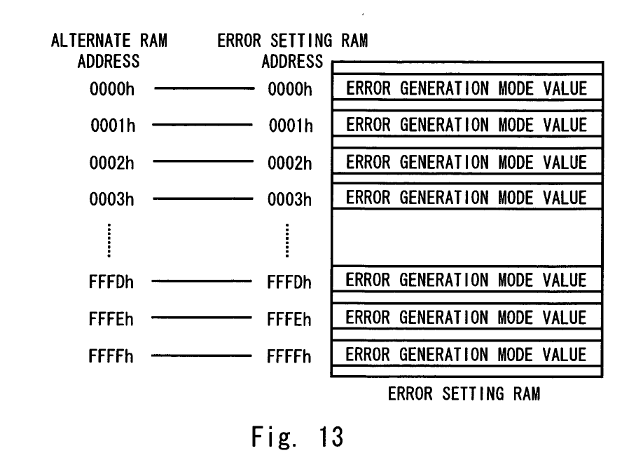

As shown in FIG. 12, the error generator 60 includes a comparator circuit 61 and the error setting RAM 62. The error setting RAM 62 is described firstly. FIG. 13 shows the relationship between the error generation mode storage areas which are set to the error setting RAM 62 and the addresses on the alternate RAM 30. For example, if the addresses of the alternate RAM 30 are set from “0000h” to “FFFFh” as shown in FIG. 13, the areas (addresses) from “0000h” to “FFFFh” are set corresponding to those addresses to the error setting RAM 62. Then, an error setting mode value is stored into the area which is specified by each address of the error setting RAM 62.

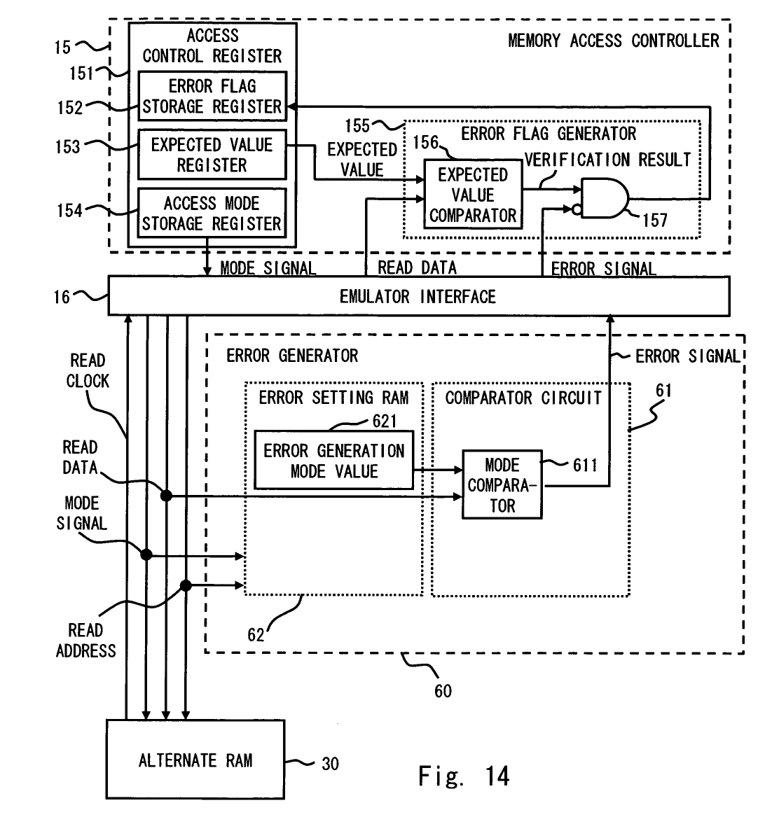

FIG. 14 is a detailed block diagram of the error generator 60. Referring to FIG. 14, a read address and a read clock are input to the error setting RAM 62. The error setting RAM 62 outputs the error generation mode value at the address of the error setting RAM 62 which is specified by the read address in synchronization with the read clock. The comparator circuit 61 includes a mode comparator 611 and compares the error generation mode value with the value of a mode signal. If the two values match, the comparator circuit 61 outputs an error signal indicating an error state (e.g. High level).

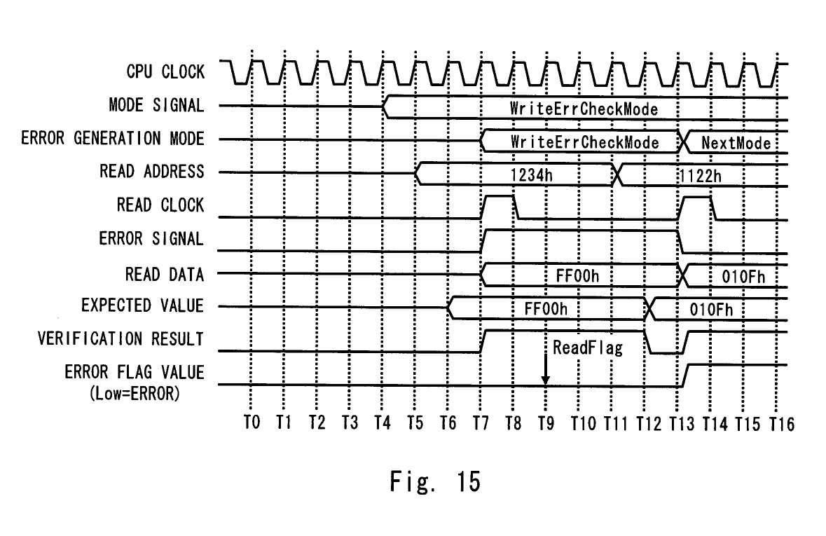

FIG. 15 is a timing chart of the operation of the evaluation system 3 according to the third embodiment. The operation of the evaluation system 3 is described hereinafter with reference to the case where an error signal is generated by the error generator 60. First, at the timing T4, the mode signal “WriteErrCheckMode”, which indicates the verification mode, is output from the evaluation microcomputer 10. Next, at the timing T5, a read address indicating the address “1234h” is output from the evaluation microcomputer 10. At the timing T6, the expected data “FF00h” of the read data is set to the expected value register 153.

Then, at the timing T7, a read clock is output from the evaluation microcomputer 10, and the read data “FF00h” is output from the alternate RAM 30 in response thereto. The read data which is output from the alternate RAM 30 is compared with the expected value by the expected value comparator 156. Because the read data value and the expected value match, the verification result is High level. Further, in response to the rising edge of the read clock at the timing T7, the error generation mode that is stored in the error setting RAM 62 which is specified by the read address is output. The error generation mode value is WriteErrCheckMode, which is the same as the mode signal value. Therefore, the error signal rises at the timing T7. Because the error signal becomes High level, the output of the AND circuit 157 forcibly becomes Low level regardless of a verification result. As a result, “0” is stored into the error flag storage register 152. The evaluation microcomputer 10 reads the error flag value at the rising edge of the CPU clock at the timing T9, thereby detecting that the read data is an error.

As described above, the evaluation system 3 of the third embodiment uses the error setting RAM 62 having the same number of addresses as the alternate RAM 30 rather than using the error setting register 23, which can also reproduce an error like the first embodiment. The use of the error setting RAM 62 eliminates the need for setting a value to an error generation address setting register, thereby saving the value setting process.

Further, in the evaluation system 3 of the third embodiment, the error setting RAM 62 may be connected externally. In such a case, it is possible to set the capacity of the error setting RAM 62 according to the capacity of the alternate RAM 30. Accordingly, it is possible to execute a program even when executing an evaluation target program on the alternate RAM 30 having a larger capacity than the capacity which is incorporated into the evaluation system 3 by appropriately selecting the capacity of the external error setting RAM 62.

It is apparent that the present invention is not limited to the above embodiments, but may be modified and changed without departing from the scope and spirit of the invention. For example, an error signal may be in synchronization with a CPU clock rather than in synchronization with a read clock. Further, although an error signal which is in synchronization with a read clock is output using the error output circuit in the first and second embodiments, it is possible to use the output of the comparator circuit as an error signal without using the error output circuit. Furthermore, although an alternate RAM is used as a substitute for a flash memory in the above-described embodiments, the present invention can be applied regardless of the type of memories.

What is claimed is:

1. An evaluation system comprising:
a storage unit;
a microcomputer to output a read address to the storage unit and execute reading; and
an error generator to generate an error signal based on a mode signal and the read address transmitted between the storage unit and the microcomputer and output the error signal, wherein
the microcomputer determines read data received from the storage unit as an error regardless of the read data when the error signal indicates an error in the read data.

2. The evaluation system according to claim 1, wherein
the error generator includes:
an error setting register to set an access condition to the storage unit for generating the error signal; and
a comparator circuit to compare a value set to the error setting register with a value of the read address or a value of the mode signal.

3. The evaluation system according to claim 2, wherein
the error setting register includes at least one pair of:
an error generation mode setting register to store a value of the mode signal to generate the error signal; and
an error generation address setting register to store a value of the read address where the error signal is generated.

4. The evaluation system according to claim 2, wherein
the error generator includes an error output circuit to output the error signal in accordance with an output of the comparator circuit, the error output circuit setting an error state of the error signal in synchronization with a read clock, which inputs to the storage unit, and clearing an error state of the error signal based on an output of the comparator circuit.

5. The evaluation system according to claim 1, wherein
the microcomputer includes an expected value comparator to compare the read data read from the storage unit with an expected value for the read data, and detects an error in the read data based on an output of the expected value comparator when the error signal indicates no error in the read data.

6. The evaluation system according to claim 1, wherein
the storage unit stores an evaluation target program including a program to control the storage unit.

7. The evaluation system according to claim 1, wherein
the storage unit is an alternate RAM used only for verification of an evaluation target program.

8. A program evaluation method to execute an evaluation target program by a microcomputer and verify an operation of the evaluation target program, comprising:
receiving read data from a storage unit based on a read clock output form the microcomputer;
outputting an error signal generated based on a mode signal and a read address transmitted between the storage unit and the microcomputer; and
determining by the microcomputer the read data as an error regardless of the read data received from the storage unit when the error signal indicates an error in the read data.

9. An evaluation system comprising:
a storage unit;
a microcomputer to output a read address to the storage unit and execute reading, the microcomputer performing verification by comparing read data output from the storage unit with an expected value for the read data to detect an error in the read data; and
an error generator to generate an error signal based on the read address, wherein
the microcomputer determines the read data as an error regardless of a result of the verification when the error signal indicates a first state.

10. The evaluation system according to claim 9, wherein
the error generator includes:
an error setting register to set an access condition to the storage unit for generating the error signal; and
a comparator circuit to compare a value set to the error setting register with a value of the read address or a value of a mode signal specifying an access mode to the storage unit.

11. The evaluation system according to claim 10, wherein
the microcomputer includes a condition setting register, and sets a value of the error setting register based on a value set to the condition setting register.

12. The evaluation system according to claim 10, wherein
the error setting register includes at least one pair of:
an error generation mode setting register to store a value of the mode signal to generate the error signal; and
an error generation address setting register to store a value of the read address where the error signal is generated.

13. The evaluation system according to claim 12, wherein
the error generator includes:
a mode comparator to compare a value of the error generation mode setting register with the mode signal output from the microcomputer; and
an address comparator to compare a value of the error generation address setting register with the read address.

14. The evaluation system according to claim 13, wherein
the error generator includes an error signal output circuit to generate an error signal based on outputs of the mode comparator and the address comparator.

15. The evaluation system according to claim 10, wherein
the error generator includes an access counter to count an access number to a condition specified by a value set to the error setting register, and sets the error signal to a second state when the access number reaches a predetermined value.

16. The evaluation system according to claim 9, wherein
the error generator includes an error setting RAM to store a value of a mode signal specifying an access mode to the storage unit to generate the error signal in each address corresponding to the read address.

17. The evaluation system according to claim 16, wherein
the error setting RAM includes the same number of addresses as addresses of the storage unit.

18. The evaluation system according to claim 9, wherein
the storage unit stores an evaluation target program, and
the microcomputer reads and executes the evaluation target program to perform reading and verification for the storage unit.

19. The evaluation system according to claim 9, wherein
the storage unit is an alternate RAM used only for verification of an evaluation target program.

20. The program evaluation method according to claim 8, wherein the outputting includes,
comparing a read address output from the microcomputer to the storage unit with an error address output from the microcomputer;
generating the error signal if the read address and the error address match as a result of the comparison; and
wherein the read data is output from the storage unit based on the read address.
